(19) United States
(12) Patent Application Publication
(10) Pub. No.: US 2017/0062688 A1
(43) Pub. Date: Mar. 2, 2017

(54) Thermally-Efficient Electrical Assembly

(71) Applicant: Johnson Electric S.A., Murten (CH)

(72) Inventors: Peng ZHU, Shang Hai (CN); Steven Eric DEAN, Intervale, NH (US); Jean-Francois ROY, Jouarre (FR)

(21) Appl. No.: 15/249,920

(22) Filed: Aug. 29, 2016

(30) Foreign Application Priority Data
Aug. 31, 2015 (CN) 2015 1055 1075.3

(51) Int. Cl. H01L 33/64; H01L 33/62

(52) U.S. Cl. CPC H01L 33/647; H01L 33/62

(57) ABSTRACT

A thermally-efficient electrical assembly comprising: an electrically-conductive layer; a heat sink layer; an electrically-insulating interconnecting layer interposed between the electrically-conductive layer and heat sink layer; an electrical component in electrical communication with the electrically-conductive layer; and a metallic thermal bridge in thermal communication with the electrical component and in direct contact with the heat sink layer, thereby bypassing the electrically-insulating layer.

### CROSS REFERENCE TO RELATED APPLICATIONS

This non-provisional patent application claims priority under 35 U.S.C. §119(a) from Patent Application No. 201510551075.3 filed in The People's Republic of China on Aug. 31, 2015, the entire contents of which are hereby incorporated by reference.

### BACKGROUND OF THE INVENTION

The present invention relates to a thermally-efficient electrical assembly for optimising heat transfer or dissipation from an electrical component. It further preferably relates to a thermally-efficient flexible circuit, and more preferably a lighting component including such a thermally-efficient flexible circuit.

The generation of heat from electrical components can have negative effects on their usefulness, in particular their efficiency and lifespan. Whilst components are being developed which are intrinsically more efficient in order to reduce waste heat, the technological advances which allow such improvements likewise result in the development of smaller yet more powerful components.

One such example is the light-emitting diode, or LED. At the beginning of their development, LEDs were low-powered and thus of limited use in many situations, although they advantageously were far more energy-efficient than equivalently bright incandescent bulbs. However, the technology of and associated with LEDs has improved to the extent at which LEDs are now able to replace incandescent bulbs or other light-sources in such high-power applications as floodlighting and vehicle headlamp clusters. However, the improvements to LED brightness have resulted in greater waste heat generation, which must be effectively dispersed to aid efficiency and also longevity of the components.

In many applications, LEDs and other heat-producing electrical components are required to be mounted directly onto circuit boards. Therefore, it is relatively common for a heat sink to be provided on or in direct contact with these circuit boards. However, the construction of circuit boards can also contribute to poor thermal dissipation. In particular, adhesive is commonly used to bond layers of the circuit board together.

The adhesive provides electrical insulation between the layers of the circuit board. This is particularly necessary when used in conjunction with a heat sink as is it important to avoid shorting any electrical circuitry through the, generally metallic, heat sink. Unfortunately, adhesive is generally poor at conducting thermal energy when compared to other materials, and therefore it can act as a partial thermal insulator.

It is therefore required to develop a more thermally-efficient construction of a circuit board, in order to dissipate waste heat away from electrical components. By doing so, more efficient and longer life components may be enabled.

It is an object of the present invention to prevent or mitigate the above problems by the implementation of a thermally-efficient electrical assembly.

### BRIEF SUMMARY OF THE INVENTION

According to a first aspect of the invention there is provided a thermally-efficient electrical assembly comprising: an electrically-conductive layer; a heat sink layer; an electrically-insulating interconnecting layer interposed between the electrically-conductive layer and heat sink layer; an electrical component in electrical communication with the electrically-conductive layer; and a metallic thermal bridge in thermal communication with the electrical component and in direct contact with the heat sink layer, thereby bypassing the electrically-insulating interconnecting layer.

According to a second aspect of the invention, there is provided a thermally-efficient flexible circuit comprising: an electrically-conductive layer forming part of a flexible printed circuit board including a flexible substrate; a heat sink layer; an electrically-insulating interconnecting layer interposed between the electrically-conductive layer and heat sink layer; an electrical component in electrical communication with the electrically-conductive layer; and a metallic thermal bridge in thermal communication with the electrical component and in direct contact with the heat sink layer, thereby bypassing the electrically-insulating interconnecting layer.

According to a third aspect of the invention, there is provided a lighting component including a thermally-efficient flexible circuit in accordance with the second aspect of the invention, wherein the electrical component is a light-emitting diode.

According to a fourth aspect of the invention, there is provided a method of effecting efficient heat transfer from an electrical component to a heat sink, the method comprising the steps of: a] providing an electrical component in electrical communication with an electrically-conductive layer and a heat sink layer, an electrically-insulative interconnecting layer being provided therebetween; and b] thermally interconnecting the electrical component and heat sink layer with a metallic thermal bridge in thermal communication with the electrical component and in direct contact with the heat sink layer, which bypasses the electrically-insulative interconnecting layer.

### BRIEF DESCRIPTION OF THE SEVERAL VIEWS OF THE DRAWINGS

The invention will now be more particularly described, by way of example only, with reference to the accompanying drawings, in which:

FIG. 1 shows a first embodiment of a thermally-efficient electrical assembly, in accordance with the first aspect of the invention;

FIG. 2 shows a second embodiment of a thermally-efficient electrical assembly in accordance with the first aspect of the invention, without a substrate layer;

FIG. 3 shows a third embodiment of a thermally-efficient electrical assembly in accordance with the first aspect of the invention, including a metallic element and a solder rivet;

FIG. 4 shows a fourth embodiment of a thermally-efficient electrical assembly in accordance with the first aspect of the invention, wherein the solder rivet is connected to a negative electrode of the electrical component.

### DETAILED DESCRIPTION OF THE INVENTION

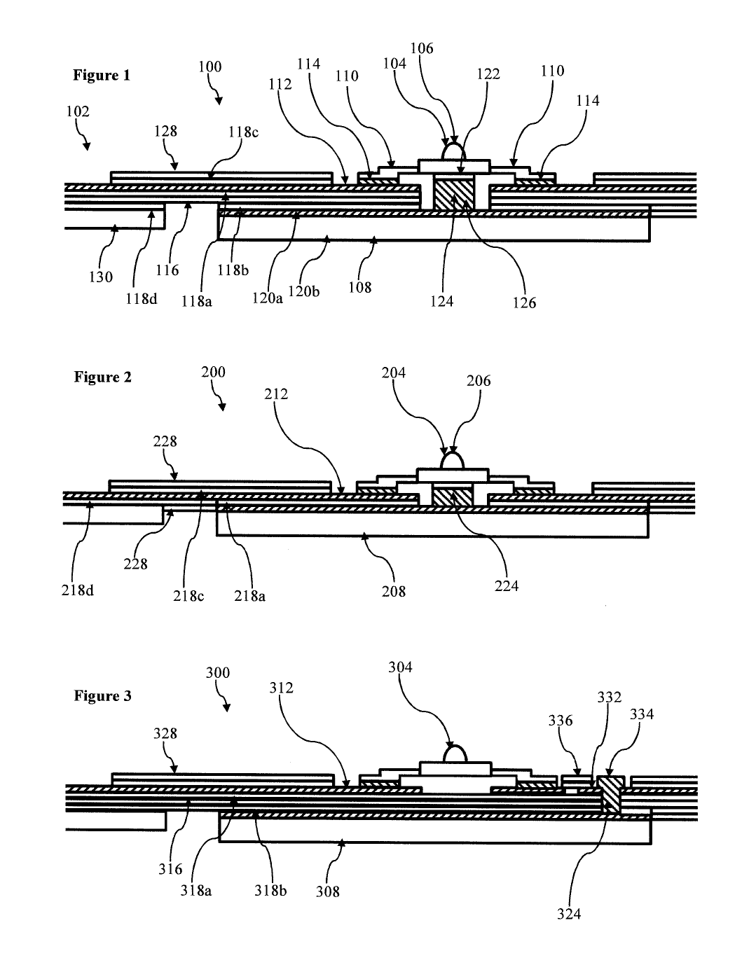

Referring firstly to FIG. 1 of the drawings, there is shown a first embodiment of the thermally-efficient electrical assembly 100 of the present invention. A cross-sectional view through a circuit board assembly 102 is shown, detailing the relationship between an electrical component 104, which in this case is a light emitting diode, or LED 106, and a heat sink layer 108.

In this embodiment, the LED 106 is mounted via two electrodes 110 to an electrically conductive layer 112, which may be a copper track or any other such material able to transmit an electrical current, such as silver. Mounting of the LED is achieved using solder connectors 114. The electrically conductive layer 112 is itself mounted to a flexible substrate layer 116 such as a polyimide film. This mounting may advantageously be achieved by use of an electrically-insulative adhesive layer 118a. The adhesive 118a is preferably an electrically-insulative or highly-resistive adhesive, to prevent or limit electrical conduction from the electrically conductive layer 112 to the flexible substrate layer 116. Whilst preferably an electrically-insulative adhesive layer, 118a, any other electrically-insulative or -resistive interconnective layer could be used instead. This flexible substrate layer 116 gives the electrically conductive layer 112 additional strength whilst still allowing the entire assembly 100 to flex as necessary. Thus, the present embodiment may be used where the electrical assembly 100 is required to flexibly conform to an enclosure, for instance in a car headlamp housing.

Whilst a flexible assembly is hereby disclosed, it is also possible for the present invention to be used in conjunction with a non-flexible circuit. Such non-flexible circuits may include silicon-based substrate layers, glass-reinforced epoxy laminate layers such as FR4, or other layers with limited or no flexibility. Such a feature does not detract from the inventive concept hereby claimed.

A further adhesive layer 118b is disposed between the flexible substrate layer 116 and the heat sink layer 108. The heat sink layer 108 itself comprises upper and lower heat-sink sub-layers 120a, 120b. The upper heat-sink sub-layer 120a in the present embodiment is preferably formed of copper. Copper is advantageously able to bond with solder, the benefits of which are clarified below. The lower heat-sink sub-layer 120b may beneficially be formed of aluminium which is both lightweight and a good conductor of thermal energy, whilst also being typically less-costly than copper. The upper and lower heat-sink sub-layers 120a, 120b may be manufactured together by way of hot rolling, for instance.

However, other combinations of materials may be used in place of those described in this embodiment. Similarly, it is possible to provide a heat sink layer formed of only one layer, which could be either copper, aluminium, or any other material which is capable of adequate heat transmission.

The LED 106 also includes a thermal pad 122, which is electrically insulated from the electrodes 110 of the LED 106. This thermal pad 122 is connected in this embodiment directly to the heat sink layer 108 via a metallic thermal bridge 124, and more particularly to the upper heat-sink sub-layer 120a. This metallic thermal bridge 124 is a solder column 126. As such, a direct, metallic thermal path is provided for the transmission or conduction of heat directly from the electrical component 104 to the heat sink layer 108.

The thermal pad 122 is also advantageously formed from copper. Copper is beneficial to the construction as it is a very capable thermal conductor and forms a strong bond with solder. As such, no intermediate material is required to interconnect the thermal bridge 124 with the thermal pad 122 and heat sink layer 108.

In this embodiment, the use of an electrically-isolated thermal pad 122 ensures that the heat sink layer 108 remains electrically isolated from the LED 106. As such, the heat sink layer 108 need not be isolated from a surrounding housing or other mounting, and the risk of electrocution arising from contact with the heat sink is significantly reduced. Furthermore, the thermal pad 122 is specifically positioned and designed for maximum thermal conduction away from the LED 106, ensuring the efficiency of the arrangement.

On portions of the electrically conductive layer 112, it may also be preferable to include a coverlay 128 which is a protective over-layer and provides a level of protection to the underlying layers. Such a coverlay 128 may be formed of polyimide, polyester, or other such suitable material and may be attached by way of adhesive to the electrically conductive layer 112. Advantageously, the coverlay 128 provides flexible protection to the other layers, which allows the circuit board assembly 102 to flex, as desired. The coverlay 128 and adhesive 118c may, for instance, be pressurised onto the required surface. Alternatively, a solder resist may be utilised in place of the coverlay 128.

It is also possible to locally rigidify portions of the flexible circuit board assembly 102 by the application of a stiffener 130. The stiffener 130 may be formed of materials such as FR4, polyimide, or polyester, with thicknesses generally ranging from 0.050 mm to 2.400 mm Again, adhesive 118d may be used to bond the stiffener 130 to the other layers of the assembly 102. Stiffening of portions of the assembly 102 may enhance the strength properties when necessary, improving the longevity of the structure, particularly in relatively harsh working environments.

In comparison to the stiffener 130, the flexible substrate layer 116 and coverlay 128 may commonly be manufactured in thicknesses of 0.012 mm to 0.125 mm. Similarly, the thickness of the adhesive 118a-d may range from 0.012 mm to 0.050 mm. These ranges of thicknesses are provided for reference only, being typical for use in such a circuit, and are not necessarily intended to limit the scope of the invention to use of layers of these thicknesses.

The above-described arrangement of the thermally-efficient electrical assembly 100 therefore provides a path for the transmission or conduction of heat energy from the electrical component 104 to the heat sink layer 108. In known arrangements, it is common for the heat to instead be dissipated from the component 104 through each of the interposed layers to the heat sink layer 108. Many of these layers, such as those used as adhesives 118a-d or in a flexible substrate layer 116, tend to conduct heat more quickly within the plane of the material rather than through the layer to underlying layers. As such, by replacing this inefficient thermal pathway with a more efficient thermal bridge 124 which bypasses these layers, the heat transfer away from the electrical component 104 can be accelerated, which may be beneficial to the working of the component 104 and circuit themselves.

FIG. 2 depicts a second embodiment of a thermally-efficient electrical assembly 200, wherein the assembly 200 has been simplified. Detailed description of similar or identical features in this and further embodiments is omitted, for brevity.

The electrical component 204, again shown as an LED 206, is similarly connected to the heat sink layer 208 by a metallic thermal bridge 224. However, the height of the thermal bridge 224 is less than that of the first embodiment due to the omission of the flexible substrate layer. Therefore, in this second embodiment, the layers of the electrical assembly 200 are limited to the electrically conductive layer 212 which is overlaid by adhesive 218c and coverlay 228 and bonded to the heat sink layer 208 with an adhesive layer 218a. The stiffener 230 is also applied with adhesive 218d, where necessary.

The flexible substrate layer may be omitted where the added strength provided is not required, the electrically conductive layer 212 and coverlay 228 being sufficient to provide both strength and flexibility to the thermally-efficient electrical assembly 200.

However, due to the reduced thickness of the electrical assembly 200, and the associated decrease in height of the thermal bridge 224, the heat transfer between the LED 206 and heat sink layer 208 may be increased further over the embodiment of FIG. 1.

In FIG. 3, a third embodiment of a thermally-efficient electrical assembly 300 is shown, featuring an electrical component 304 which does not include a thermal pad. The electrical assembly 300 includes an electrically conductive layer 312, on which is attached the electrical component 304. An electrically-isolated metallic element 332, also formed of copper in this embodiment, is formed adjacent to, but separated from, the electrically conductive layer 312. Again, references which are similar to those of the first and second embodiments refer to the same or similar components, and further detailed description is omitted.

The metallic element 332, whilst being electrically-isolated, is thermally-coupled to the electrically conductive layer 312 and thus to the electrical component 304. A thermal bridge 324, formed in this case as a solder rivet 334, provides a direct metallic connection between the metallic element 332 and the heat sink layer 308. As such, the thermal bridge 324 passes through the interposed flexible substrate layer 316 and adhesive layers 318a, 318b, providing a thermal bypass to the heat sink layer 308.

The metallic element 332 is thermally-coupled to the electrically conductive layer 312 by a thermal couple 336. The thermal couple 336 is hereby formed of a portion of the coverlay 328, but could otherwise be formed of any other material which provides thermally-conductive and electrically-insulative properties. As the distance spanned by the thermal couple 328 is less than that between the electrical component 304 and the heat sink layer 308, the resistance to thermally-efficient heat transfer is limited. As such, this third embodiment of the thermally-efficient electrical assembly 300 is still an improvement over the previously known arrangements.

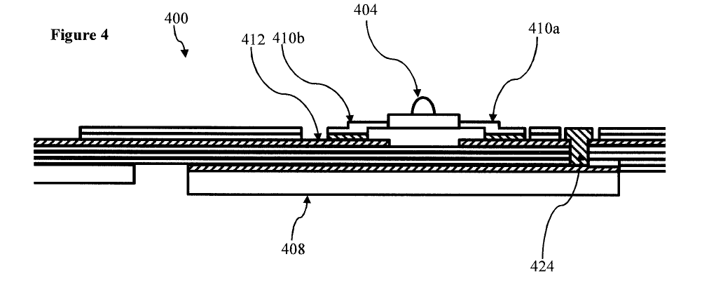

The thermally-efficient electrical assembly 400 of the fourth embodiment shown in FIG. 4 is largely similar to that of FIG. 3, but there is no metallic element or thermal couple, and therefore no isolation between the thermal bridge 424 and the heat sink layer 408. As such, there is lower resistance to thermal conduction than in the third embodiment. As before, references which are similar to those of the preceding embodiments refer to the same or similar parts, and detailed description is omitted for brevity.

The thermal bridge 424 is preferably attached to a negative electrode 410a of the electrical component 404 such that it is subject to a lower voltage than that at the positive electrode 410b. However, as the thermal bridge 424 is connected as such, the heat sink layer 408 may also therefore be subject to increased voltage.

Beneficially, this arrangement may be more thermally-efficient than the third embodiment, due to the lack of the thermal couple 336. However, as the heat sink layer 408 and thermal bridge 424 are electrically-connected to the electrically conductive layer 412, they should preferably be electrically-isolated from other portions of an assembly 400, in use. For instance, when in a car, they should be electrically-isolated from the headlamp housing, to prevent accidental electrocution of anyone coming into contact with the housing.

Whilst the above embodiments have been discussed in relation to an LED, any other electrical component may be used in conjunction with the thermally-efficient electrical assembly. The assembly is most beneficial when used with electrical components which have a high thermal output such as LEDs, transformers, or other such components, but is likely to have beneficial effects for any electrical component which outputs heat to a circuit.

Furthermore, there is no reason why the disclosed invention should be used only with flexible circuits. Non-flexible circuits may also benefit from the arrangement, the only difference being the constituent layers of the circuit board; for instance the substitution of the flexible substrate layer with a non-flexible substrate layer. The underlying concept of the thermal bridge which bypasses the in-between layers of the circuit board may remain constant. Advantageously, any substrate layer may be dielectric in order to provide enhanced electrical insulation properties.

It is therefore possible to provide a thermally-efficient electrical assembly, having a metallic thermal bridge providing good heat conduction between an electrical component and a heat sink layer, the metallic thermal bridge bypassing any intervening layers.

The words ‘comprises/comprising’ and the words ‘having/including’ when used herein with reference to the present invention are used to specify the presence of stated features, integers, steps or components, but do not preclude the presence or addition of one or more other features, integers, steps, components or groups thereof.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

The embodiments described above are provided by way of examples only, and various other modifications will be apparent to persons skilled in the field without departing from the scope of the invention herein described and defined.

What is claimed is:

1. A thermally-efficient electrical assembly comprising:
an electrically-conductive layer;
a heat sink layer;
an electrically-insulating interconnecting layer interposed between the electrically-conductive layer and heat sink layer;
an electrical component in electrical communication with the electrically-conductive layer; and
a metallic thermal bridge in thermal communication with the electrical component and in direct contact with the heat sink layer, thereby bypassing the electrically-insulating interconnecting layer.

2. The thermally-efficient electrical assembly as claimed in claim 1, wherein the electrically-insulating interconnecting layer is an electrically insulating adhesive layer.

3. The thermally-efficient electrical assembly as claimed in claim 1, wherein the heat sink layer includes upper and lower heat-sink sub-layers, the upper heat-sink sub-layer being bonded to the electrically-conductive layer.

4. The thermally-efficient electrical assembly as claimed in claim 3, wherein the upper heat-sink sub-layer comprises copper.

5. The thermally-efficient electrical assembly as claimed in claim 3, wherein the lower heat-sink sub-layer comprises aluminium.

6. The thermally-efficient electrical assembly as claimed in claim 1, wherein the electrically-conductive layer is additionally bonded to a substrate layer.

7. The thermally-efficient electrical assembly as claimed in claim 6, wherein the substrate layer includes polyimide.

8. The thermally-efficient electrical assembly as claimed in claim 1, wherein the metallic thermal bridge includes solder.

9. The thermally-efficient electrical assembly as claimed in claim 8, wherein the metallic thermal bridge is a solder rivet.

10. The thermally-efficient electrical assembly as claimed in claim 1, wherein the electrical component includes a thermal pad, the metallic thermal bridge being in direct contact with both the thermal pad and the heat sink layer.

11. The thermally-efficient electrical assembly as claimed in claim 1, further comprising a metallic element, electrically-isolated from and in thermal communication with the electrical component, the metallic thermal bridge being in direct contact with both the metallic element and the heat sink layer.

12. The thermally-efficient electrical assembly as claimed in claim 11, wherein the metallic element is a copper element.

13. The thermally-efficient electrical assembly as claimed in claim 1, wherein the thermal bridge is directly connected to a negative electrode of the electrical component.

14. The thermally-efficient electrical assembly as claimed in claim 1, wherein the electrical component is a light-emitting diode.

15. A thermally-efficient flexible circuit comprising:
an electrically-conductive layer forming part of a flexible printed circuit board including a flexible substrate;
a heat sink layer;
an electrically-insulating interconnecting layer interposed between the electrically-conductive layer and heat sink layer;
an electrical component in electrical communication with the electrically-conductive layer; and
a metallic thermal bridge in thermal communication with the electrical component and in direct contact with the heat sink layer, thereby bypassing the electrically-insulating interconnecting layer.

16. A lighting component including a thermally-efficient flexible circuit as claimed in claim 15, wherein the electrical component is a light-emitting diode.

17. A method of effecting efficient heat transfer from an electrical component to a heat sink, the method comprising the steps of:
a] providing an electrical component in electrical communication with an electrically-conductive layer and a heat sink layer, an electrically-insulative interconnecting adhesive layer being provided therebetween; and
b] thermally interconnecting the electrical component and heat sink layer with a metallic thermal bridge in thermal communication with the electrical component and in direct contact with the heat sink layer, which bypasses the electrically-insulative interconnecting layer.
